(19) United States
(12) Patent Application Publication
(10) Pub. No.: US 2013/0319855 A1
(43) Pub. Date: Dec. 5, 2013

(54) MAGNETRON SPUTTERING SYSTEM

(71) Applicant: Jinlei Li, Guangdong (CN)

(72) Inventor: Jinlei Li, Guangdong (CN)

(73) Assignee: SHENZHEN CHINA STAR OPTOELECTRONICS TECHNOLOGY CO. LTD., Guangdong (CN)

(21) Appl. No.: 13/636,975

(22) PCT Filed: Jul. 23, 2012
(86) PCT No.: PCT/CN12/78995

§ 371 Date: Sep. 24, 2012

(30) Foreign Application Priority Data
Jun. 4, 2012 (CN) 201210180912.2

(51) Int. Cl. C23C 14/35

(52) U.S. Cl. 204/298.11; 204/298.15

(57) ABSTRACT

A magnetron sputtering system is disclosed in the present invention. A chamber includes a target holder, a substrate holder and a magnetic-field generating component. The magnetic-field generating component is configured to generate a magnetic field in a surrounding area of a substrate to be sputtered and deposited. The present invention can avoid the charged molecules and the cathode ions generated by the target hitting the to-be-sputtered/deposited substrate with higher energy. Therefore, it can avoid the damage of the to-be-sputtered/deposited substrate and decrease the stress of depositing the thin film on the substrate, as so to increase the yield of the products.

### FIELD OF THE INVENTION

The present invention relates to a field of liquid crystal display (LCD) manufacturing technology, and more particularly to a magnetron sputtering system.

### BACKGROUND OF THE INVENTION

According to the continuous development of the liquid crystal display (LCD), the requirement of the manufacturing efficiency of the LCD is increased.

For a magnetron sputter system as an example, because the magnetron sputtering system can deposit a film in a large area of a substrate, the deposited film is even and the adhesive force of the deposited film on the substrate is high. Therefore, the magnetron sputtering system is widely used in the LCD manufacturing technology, especially in the thin film depositing manufacturing technology.

During the LCD manufacturing process, the magnetron sputtering system can deposit a metal thin film or a metal oxide transparent electrode thin film. The metal film is, for example, aluminum (Al), alloy of aluminum and rubidium (AlNd), molybdenum (Mo), or Copper (Cu). The metal oxide transparent electrode thin film is, for example, Indium Tin Oxide (ITO), Indium Zinc Oxide (IZO) and so on. For example, in manufacturing Organic Light-Emitting Diode (OLED), the magnetron sputtering system can be used to deposit the thin film on a cathode layer and an anode layer, which are located at two sides of the light-emitting layer.

Please refer to FIG. 1, which is a structural view illustrating a conventional magnetron sputtering system when sputtering and depositing a thin film. The magnetron sputtering system 10 includes a metal chamber 11, which is configured to separate from the external environment, so as to preserve the vacuum space of the metal chamber 11. The metal chamber 11 includes a target holder 12 and a substrate holder 13 therein. The target holder 12 and the substrate holder 13 are oppositely disposed. There are magnets 14 disposed inside the target holder 12.

When the magnetron sputtering system 10 is used to sputter and deposit the film on the substrate 16, the target 15 is fixed on the target holder 12, and the substrate 16 is disposed on the substrate holder 13. The target 15 is connected to the cathode of the power source (not shown), and the metal chamber 11 and the substrate 16 are connected to the anode of the power source. Furthermore, the metal chamber 11 is filled with argon atoms by an inert gas tube (not shown). After connecting to the power source, an electric field is generated between the target 15 and the substrate 16 and the electrons between the target 15 and the substrate 16 are moving fast because of the effect of the electric field. The electrons hit the argon atoms within the metal chamber 11 to generate argon positive ions (Ar⁺) and new electrons by ionizing. The Ar⁺ ions move in a rapid speed to the target 15 by the electric field and hit the surface of the target 15 with higher energy.

Because the magnets 14 are disposed within the target holder 12, the magnets 14 will generate a magnetic field. The surface of the target 15 not only includes the electric field but also includes the magnetic field. When the Ar+ ions hit the surface of the target 15 to release secondary electrons, the secondary electrons are constrained in an area close to the surface of the target 15 by the effect of the magnetic field. By the joint effect of the electric field and the magnetic field, the moving path of the secondary electrons are along the electric field to speed up the secondary electrons and the secondary electrons would circle around the magnetic field to move in a complicated curve direction so as to increase the length of the moving path of the secondary electrons. During the moving process, the secondary electrons keep hitting the argon atoms within the metal chamber 11 to ionize a lot of Ar⁺ ions to hit on the target 15.

Because the target 15 is connected to the cathode of the power source and the hitting speed of the Ar⁺ ions is high, the target 15 is sputtered to generate target atoms, molecules or positive ions. The neutron target atoms are deposit on the surface of the substrate 16 to form a thin film so as to coat the film on substrate. After the charged molecules or positive ions generated by the sputtering of the target 15 are moving away from the target 15, the charged molecules or positive ions are sputtered on the substrate 16 with higher energy (such as dozen of electronvolt(eV)s) by the effect of the magnetic field. The charged molecules or positive ions are sputtered in a linear moving manner to the substrate 16 and the surrounding area of the substrate 16. When the charged molecules or positive ions hit the substrate 16 with higher energy, the surface of the substrate 16 would be easily damaged and the stress of the deposited thin film on the substrate 16 is greater. Especially during the OLED manufacturing process, the cathode thin film is deposited on the light emission layer, which is made of organic plastic molecule, the charged molecules or the cathode ions generated by sputtering the target 15 are easy to damage the light emission layer so as to decrease the yield of the products.

As the description above, how to avoid the damage of the substrate because of the generation of the charged molecules or the cathode ions to decrease the stress of the deposited thin film is one of technique problems in the LCD manufacturing technology required to be solved.

### SUMMARY OF THE INVENTION

An object of the present invention is to provide a magnetron sputtering system to avoid the damage of the substrate caused by the charged molecules or cathode ions and the decrease of the stress of the thin film depositing.

For achieving the above-mentioned resolution, the present invention proposes a magnetron sputtering system including a chamber, and the chamber includes a target holder and a substrate holder, and the substrate holder is configured to dispose a substrate to be sputtered and deposited, wherein the magnetron sputtering system further includes a magnetic-field generating component, and the magnetic-field generating component is disposed within the substrate holder and configured to generate a magnetic field in a surrounding area of the to-be-sputtered/deposited substrate;

a shielding board is disposed between the magnetic-field generating component and a bottom of the chamber, and the substrate holder includes an anti-shielding board, which is configured to dispose the to-be-sputtered/deposited substrate, and the shielding board is made of a magnetic conductive material and the anti-shielding board is made of a non-magnetic conductive material.

In one embodiment of the present invention, the anti-shielding board is integrated with the substrate holder.

In one embodiment of the present invention, the magnetic-field generating component includes at least two permanent magnet plates, and the at least two permanent magnet plates are equidistantly arranged along a horizontal direction and the horizontal direction is perpendicular to a direction where the to-be-sputtered/deposited substrate is passes through the chamber.

In one embodiment of the present invention, along the horizontal direction, a width formed by the at least two permanent magnet plates is greater than a width of the to-be-sputtered/deposited substrate; and along the direction where the to-be-sputtered/deposited substrate passes through the chamber, a length in each of the permanent magnet plate is greater than a length of the to-be-sputtered/deposited substrate.

In one embodiment of the present invention, the at least two permanent magnet plates includes a first permanent magnet plate and a second permanent magnet plate, both of which are alternatively arranged, and a polarity of the first permanent magnet plate is different from a polarity of the adjacent second permanent magnet plate.

In one embodiment of the present invention, a permanent magnet wedge is disposed between the anti-shielding board and the permanent magnet plate, a shape of the permanent magnet wedge is wedge, and a polarity of the permanent magnet wedge is the same as a polarity of the corresponding permanent magnet plate.

In one embodiment of the present invention, the magnetron sputtering system further includes a first horizontal motion controller configured to control the at least two permanent magnet plates to move back and forth along the horizontal direction.

In one embodiment of the present invention, a vertical direction is perpendicular to a horizontal surface of the anti-shielding board;

the magnetron sputtering system further includes a second horizontal motion controller configured to control the at least two permanent magnet plates to move along the vertical direction.

Another object of the present invention is to provide a magnetron sputtering system to avoid the damage of the substrate caused by the charged molecules or cathode ions and the decrease of the stress of the thin film depositing.

For achieving the above-mentioned resolution, the present invention proposes a magnetron sputtering system including a chamber, and the chamber includes a target holder and a substrate holder, and the substrate holder is configured to dispose a to-be-sputtered/deposited substrate;

the magnetron sputtering system further includes a magnetic-field generating component, and the magnetic-field generating component is configured to generate a magnetic field in a surrounding area of the to-be-sputtered/deposited substrate.

In one embodiment of the present invention, the magnetic-field generating component is a permanent magnet plate, which is disposed within the substrate holder.

In one embodiment of the present invention, the substrate holder includes an anti-shielding board, which is configured to dispose the to-be-sputtered/deposited substrate, and the anti-shielding board is integrated with the substrate holder and made of non-magnetic conductive material.

In one embodiment of the present invention, a shielding board is disposed between the permanent magnet plate and a bottom of the chamber and is made of magnetic conductive material.

In one embodiment of the present invention, the magnetic-field generating component includes at least two permanent magnet plates, and the at least two permanent component magnet plates are equidistantly arranged along a horizontal direction, wherein the horizontal direction is perpendicular to a direction where the substrate passes through the chamber.

In one embodiment of the present invention, along the horizontal direction, a width formed by the at least two permanent magnet plates is greater than a width of the to-be-sputtered/deposited substrate; and along the direction where the substrate passes through the chamber, a length in each of the permanent magnet plates is greater than a length of the to-be-sputtered/deposited substrate.

In one embodiment of the present invention, at least two permanent magnet plates are a first permanent magnet plate and a second permanent magnet plate, both of which are alternative arranged, and a polarity of the first permanent magnet plate is different from a polarity of the adjacent second permanent magnet plate.

In one embodiment of the present invention, a permanent magnet wedge is disposed between the anti-shielding board and the permanent magnet plate, a shape of the permanent magnet wedge is wedge, and a polarity of the permanent magnet wedge is the same as a polarity of the corresponding permanent magnet plate.

In one embodiment of the present invention, the magnetron sputtering system further includes a first horizontal motion controller configured to control the at least two permanent magnet plates to move back and forth along the horizontal direction.

In one embodiment of the present invention, a vertical direction is perpendicular to a horizontal surface of the anti-shielding board;

the magnetron sputtering system further includes a second horizontal motion controller configured to control the at least two permanent magnet plates to move along the vertical direction.

In comparison with the conventional technique, the present invention implements a permanent magnet plate disposed at the bottom of the to-be-sputtered/deposited substrate to be a magnetic-field generating component, and the permanent magnet plate will generate a magnetic field on the surface of the substrate. During sputtering the target, the magnetic field can generate a magnetic effect to the charged molecules and the cathode ions, which are irradiated to the substrate. Therefore, the problem that the charged molecules and the cathode ions hit on the substrate can be avoided. The damage of the substrate can be prevented and the stress of depositing the thin film can be decreased, so as to increase the yield of the products.

The above-mentioned description of the present invention can be best understood by referring to the following detailed description of the preferred embodiments and the accompanying drawings.

### DESCRIPTION OF THE DRAWINGS

FIG. 1 is a structural view illustrating a conventional magnetron sputtering system;

FIG. 2 is a structural view illustrating a first preferred embodiment of a magnetron sputtering system in the present invention;

FIG. 3 is a structural view illustrating the permanent magnetic plate and the anti-shielding board in FIG. 2;

FIG. 4 is a structural view illustrating the permanent board, the anti-shielding board and the shielding board in FIG. 2;

FIG. 5 is a structural view illustrating a first preferred embodiment in the present invention, as shown in FIG. 2, when the substrate is doing a sputtering and depositing process;

FIG. 6 is a view illustrating a result that a magnetic field is generated on the permanent magnet plate of FIG. 5;

FIG. 7 is a structural view of sputtering and depositing onto an OLED plate in the first preferred embodiment shown in FIG. 2;

FIG. 8 is a structural view illustrating a second preferred embodiment of the magnetron sputtering system in the present invention;

FIG. 9 is a view illustrating the magnetic field result in the second preferred embodiment of FIG. 8; and

FIG. 10 is a structural view illustrating an integration of a permanent magnet wedge and a permanent magnet plate in FIG. 8.

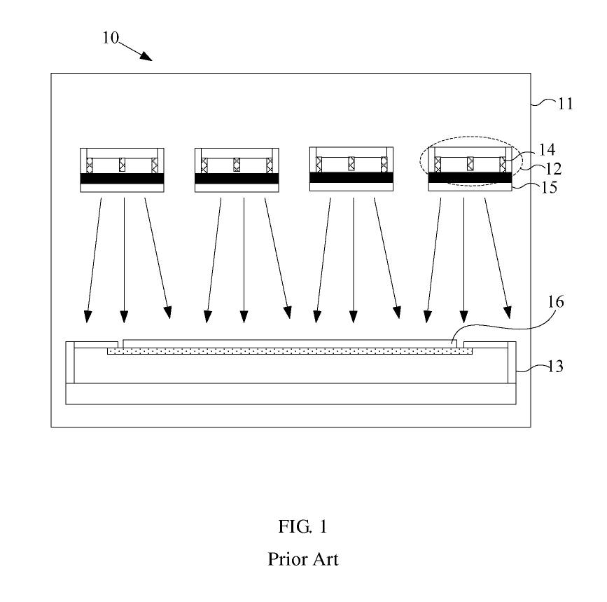

### DETAILED DESCRIPTION OF THE PREFERRED EMBODIMENTS

In the following detailed description of the preferred embodiments, reference is made to the accompanying drawings which form a part hereof, and as shown by way of illustration specific embodiments in which the invention may be practiced. In this regard, directional terminology, such as “top,” “bottom,” “front,” “back,” “left,” “right,” “inside,” “outside,” “side,” etc., is used with reference to the orientation of the Figure(s) being described. As such, the directional terminology is used for purposes of illustration and is in no way limiting the present invention.

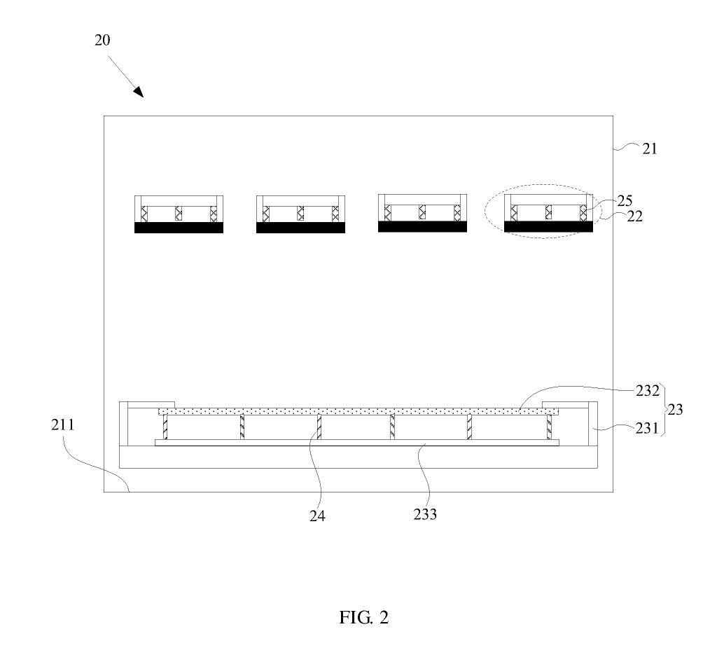

Please refer to FIG. 2, which is a structural view illustrating a first preferred embodiment of a magnetron sputtering system in the present invention. The magnetron sputtering system 20 includes a chamber 21 made of a metal material. The chamber 21 includes a target holder 22, a substrate holder 23 and a plurality of magnetic-field generating components. The magnetic-field generating components are a plurality of permanent magnet plates 24. The permanent magnet plates 24 are metal materials, such as ferrite, Neodymium iron boron and so on. The permanent magnet plates 24 are configured to be the magnetic-field generating components to generate a magnetic field.

The substrate holder 23 and the target holder 22 are oppositely disposed. The chamber 21 includes at least one target holder 22 and the target holder 22 includes at least one magnet 25.

Please still refer to FIG. 2, the substrate holder 23 include a holder main body 231 and an anti-shielding board 232 fixed on the holder main body 231. The anti-shielding board 232 is integrated with the holder main body 231. Alternatively, the anti-shielding boards 232 can be connected to the holder main body 231 by any different methods, such as bolting method. The anti-shielding board 232 is preferredly made of non-magnetic conductive metal, such as aluminum (Al), copper (Cu) and so on, to guarantee that the magnetic field generated by the permanent magnet plate 24 can pass through the anti-shielding board 232.

The permanent magnet plate 24 is disposed within the substrate holder 23 and there is a shielding board 233 disposed between the permanent magnet plate 24 and a bottom surface 211 of the chamber 21. More practically, the shielding board 233 and the anti-shielding board 232 are respectively disposed at two ends of the permanent magnet plate 24, and the shielding board 233 is disposed within the substrate holder 23. The shielding board 233 is made of magnetic conductive material, such as magnetic conductive iron, nickel and so on. The shielding board 233 made of the magnetic conductive material can shield from the magnetic field generated by the permanent magnet plate 24 to avoid that the magnetic field generated by the permanent magnet plate 24 affects other components in the magnetron sputtering system 20.

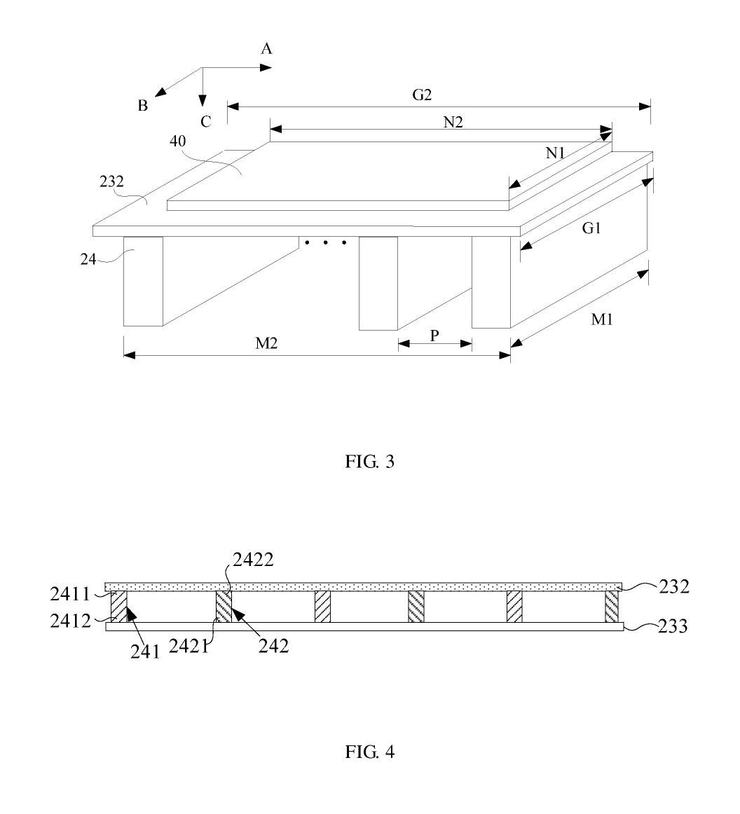

Please refer to FIG. 2 and FIG. 3, which is a structural view illustrating the permanent magnetic plate and the anti-shielding board in FIG. 2. A direction B is a moving direction of the substrate 40 in the magnetron sputtering system 20. A horizontal direction A is paralleled to the horizontal surface of the anti-shielding board 232 and perpendicular to the direction B. In the present invention, the permanent magnet plate 24 is a longitudinal shape and the length direction is direction B. Along the horizontal A, at least two of the permanent magnet plates 24 are evenly arranged with an interval P. Along the direction B, the substrate 40 includes a length N1, the anti-shielding board 232 includes a length G1 and the substrate 40 includes a length N1, wherein G1>M1 and M1>N1. Along the horizontal direction A, at least two of the permanent plates are formed a width M2. The width M2 is the width from the external side of the first permanent magnet plate to the external side of the first permanent magnet plate along the horizontal direction in FIG. 3. The width M2 is formed by the widths in each of the permanent magnet plate 24 and the intervals P between the permanent magnet plates 24. Along the direction A, the anti-shielding board 232 includes a width G2, and the substrate 40 includes a width N2, wherein G2>M2 and M2>N2. In the present invention, the length G1 of the anti-shielding board 232 is greater than the length M1 of the permanent magnet plate 24 and the width G2 of the anti-shielding board 232 is greater than the width M2 formed by at least two of the permanent magnet plates 24. Therefore, it is guaranteed that the permanent magnet plate 24 would not be damaged by sputtering on the substrate 40. The length G1 of the anti-shielding board 232 is greater than the length N1 of the substrate 40 and the width G2 of the anti-shielding board 232 is greater than the width N2 of the substrate 40 so as to guarantee that the substrate 40 can be fixed on the anti-shielding board 232.

Please refer to FIG. 4, the permanent magnet plate 24 includes a first permanent magnet plate 241 and a second permanent magnet plate 242. The first permanent magnet plate 231 and the second permanent magnet plate 242 are alternatively arranged. The polarity of the first permanent magnet plate 231 is different from the polarity of the adjacent second permanent magnet plate 232. Practically, in FIG. 4, the first permanent magnet plate 241 is close to one end of the anti-shielding board 232, which is a first anode end 2411 and one end close to the shielding board 233 is a first cathode end 2412. The second permanent magnet plate 242 is close to one end of the anti-shielding board 232, which is a second cathode end 2422 and one end close to the shielding board 233 is a second anode end 2421.

The magnetron sputtering system 20 disclosed in the present invention further includes a first horizontal motion controller and a second horizontal motion controller (not shown). The first horizontal motion controller is configured to control at least two of the permanent magnet plates 24 to move back and forth along the horizontal direction A. A vertical direction C is perpendicular to the direction of the horizontal of the anti-shielding board 232 (as shown in FIG. 3). The second horizontal motion controller is configured to control at least two of the permanent magnet plates 24 to move along the vertical direction C so as to achieve the back-and-forth movement between the permanent magnet plate 24 and the anti-shielding board 232.

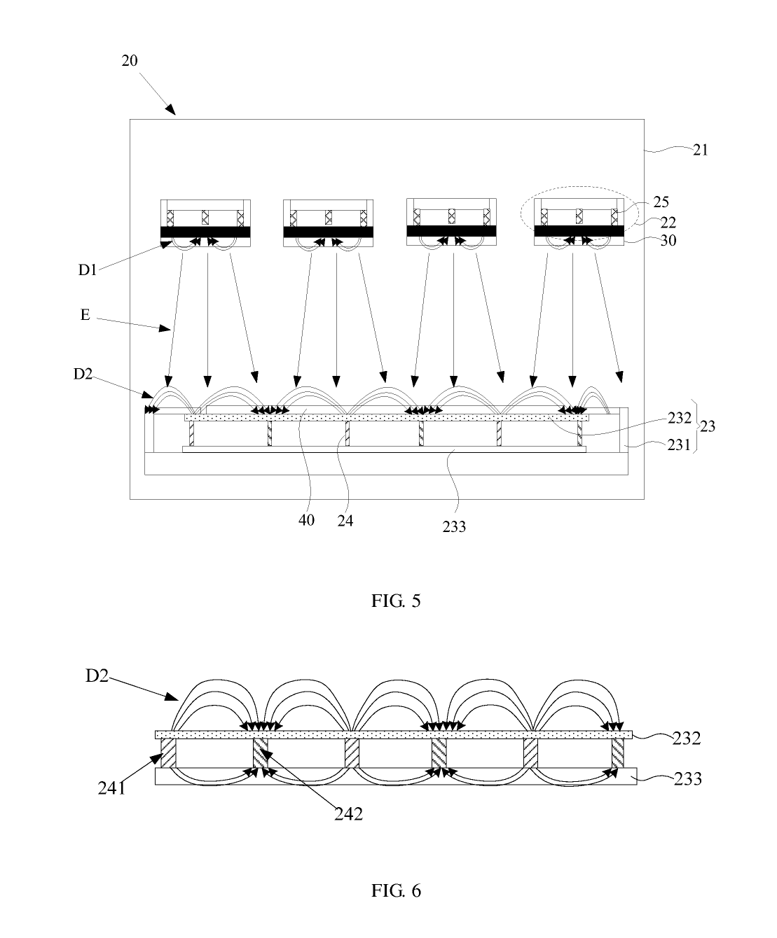

The magnetron sputtering system 20 disclosed in the present invention further includes a power source and an inert gas tube (not shown). Please refer to FIG. 2, FIG. 3, FIG. 4 and FIG. 5, FIG. 5 is a structural view illustrating the sputtering and depositing process on the substrate 40. The cathode of the power source is connected to the target 30 and the anode of the power source is connected to the chamber 21 and the substrate 40. When the sputtering and depositing process is executed on the substrate 40, the inert gas tube will provide inert gas, such as Ar atoms, to the internal of the chamber 21 and the power source is configured to provide DC voltage so as to generate an electric field between the target 30 and the substrate 40. The power source can also provide AC voltage and the detail operation thereof is omitted herein.

The working principle of the first preferred embodiment of the magnetron sputtering system shown in FIG. 2-FIG. 5 is described as the following:

Before the sputtering and depositing process is executed on the substrate 40, the target 30 is fixed on the target holder 22 and the substrate 40 is disposed on the anti-shielding board 232 of the substrate holder 23.

Thereafter, the magnetron sputtering system is connected to the power source and the inert gas, such as Ar atoms, is inputted from the inert gas tube to the internal space of the chamber 21. Because the cathode of the power source is connected to the target 30 and the anode of the power source is connected to the chamber 21 and the substrate 40, an electric field E is generated between the target 30 and the substrate 40 when the power source is turned on. Because of the electric field E, the argon in the chamber 21 is ionized to be argon position (Ar⁺) ions and electrons. The Ar⁺ ions will move in a faster speed toward the target in accordance with the effect of the electric field E and hit the surface of the target 30 with higher energy. Because the target 30 is connected to the cathode of the power source and hit by the Ar⁺ ion with higher energy, the target 30 is sputtered to generate target atoms, charged molecules and cathode ions.

Moreover, the Ar+ ions will release second electrons when the Ar⁺ ions hit on the target 30. The magnet 25 is disposed inside the target holder 22 and the magnet 25 will generate the magnetic field D1. Because of the effect of the electric field E and the magnetic field D1, the second electrons will circle on the surface of the target 30 in a cycloid way. The moving path of the circular motion is shorter and is limited within the area close to the surface of the target 30. A lot of the Ar⁺ ions are generated in the area to hit the target 30 and the target 30 will be sputtered to generate the target atoms, the charged molecules and the cathode ions are moving to the substrate 40 in a very fast speed.

The permanent magnet plate 24 generates a magnetic field D2. Please refer to FIG. 6, which is a view illustrating the result that the magnetic field D2 is generated in the permanent magnet plate 24. When the target 30 is sputtered to generate the target atoms, the charged molecules and the cathode ions with higher energy (such as dozen of eVs) to the substrate 40 or the surrounding area of the substrate 40, the neutron target atoms are sputtered on the substrate 40 to form the thin film. The charged molecules and the cathode ions will be sputtered on the substrate 40 in an irregular and circled way because of double effects of the electric field E and the magnetic field D2 instead of being sputtered in a linear way. Because the distance that the charged molecules and the cathode ions are moving to the substrate 40 is increased, the bumping opportunity is increased. The energy is consumed because of the circled moving and the mutual bumping, and the energy of the charged molecules and the cathode ions is become smaller when arriving to the substrate 40. When the target atoms, the charged molecules and the cathode ions are deposited on the substrate 40, the damages on the substrate 40 or other film layers on the substrate 40 is become smaller and the stress of the thin film depositing is correspondingly increased.

Because the permanent magnet plates 24 are evenly arranged along the horizontal direction A, it could guarantee that the magnetic field is evenly generated. Because the first permanent magnet plate 241 and the second permanent magnet plate 242 are alternatively arranged and the polarity of the first permanent magnet plate 241 is different from the adjacent second permanent magnet plate 242 so as to guarantee the even generation of the magnetic field D2. The magnetic force generated by the magnetic field D2 is evenly irradiated to the charged molecules and the cathode ions on the substrate 40 to guarantee the coating result of the thin film.

Moreover, when the sputtering and depositing process is executed on the substrate 40, the first horizontal motion controller of the magnetron sputtering system can control the permanent magnet plate 24 to move back and forth along the horizontal direction A. The total magnetic force of the magnetic field D2 on the surface of the substrate 40 is more even to enhance the even property of the generation of the thin film.

The second horizontal motion controller of the magnetron sputtering system can control the permanent magnet plate 24 to move along the vertical direction C to achieve the back-and-forth adjusting between the permanent magnet plate 24 and the anti-shielding board 232. For example, when the distance between the permanent magnet plate 24 and the anti-shielding board 232 is smaller, the magnetic force of the magnetic field D2 on the substrate 40 is increased. When the charged molecules and the cathode ions sputtered by the target 30 are arrived on the substrate 40, the measure of weight of the circular motion is increased and the bumping opportunity among the charged molecules, the cathode ions and the target atoms is increased. Therefore, the energy lost on the substrate is increased. On the contrary, when the distance between the permanent magnet plate 24 and the anti-shielding board 232 is increased and the charged molecules and the cathode ions sputtered by the target 30 are arrived on the substrate 40, the measure of weight of the circular motion is decreased and the measure of weight of the linear motion is increased. Therefore, the bumping opportunity among the charged molecules, the cathode ions and the target atoms is decreased and the higher energy is arrived on the substrate 40. Therefore, the distance between the permanent magnet plate 24 and the anti-shielding board 232 can be adjusted properly in accordance with the material of the target 30 and the material of the anti-shielding board 232 in the present embodiment. When the damage of the substrate 40 is decreased, the stress of the thin film depositing is small and the even quality is better.

Along the horizontal direction A, the width M2 generated in at least two of the permanent magnet plates 24 is greater than the width N2 of the substrate 40. Along the vertical direction B, the length M1 of the permanent magnet plate 24 is greater than the length N1 of the substrate 40 to guarantee the magnetic field D2 can completely cover the substrate 40 and avoid the edge effect on the magnetic field D2. Therefore, magnetic force D2 on the surface of the substrate 40 is even.

Because the magnetic field D2 is attenuated very fast, such as a distance 5 cm˜10 cm from the surface of the substrate 40, the magnetic field D2 will be attenuated very fast. Because the distance between the substrate 40 and the target 30 is about 15 cm in the magnetron sputtering system 20, the magnetic field D2 generated by the permanent magnet plate 24 will not affect the magnetic field D1 on the surface of the target 30.

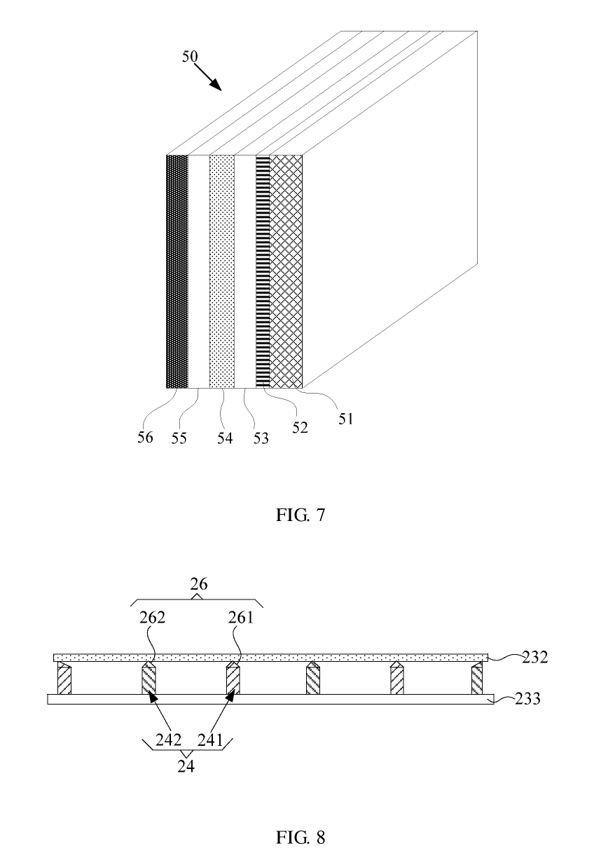

Please refer to FIG. 7, which is a structural view illustrating the OLED plate 50 is coated by the magnetron sputtering system. The OLED plate 50 includes a glass substrate 51, a first electric layer (an anode layer) 52, a concave transmitting layer 53, a light emitting layer 54, an electric transmitting layer 55 and a second electric layer (a cathode layer) 56. The second electric layer 56 is formed on the electric transmitting layer 55 by sputtering and coating process, and the light emitting layer 54 and the electric transmitting layer 55 are made of organic plastic materials. By using the magnetron sputtering system in the present invention, when the second electric layer 56 is formed and the target atoms, the charged molecules and the cathode ions generated by sputtering the target 30 are in the electric transmitting layer 55, it is guaranteed that the energy is greatly decreased so as to prevent the damage of the electric transmitting layer 55. The second electric layer 56 is evenly deposited and the yield of the products is guaranteed.

FIG. 8 is structural view illustrating a second preferred embodiment of the magnetron sputtering system in the present invention.

The difference between the second embodiment in FIG. 8 and the first embodiment in FIG. 2 is that the magnetron sputtering system in the second preferred embodiment of FIG. 8 further includes a permanent magnet wedge 26 and the shape of the permanent magnet wedge 26 is wedge. The permanent magnet wedge 26 is made of magnetic conductive material and disposed between the anti-shielding board 232 and the permanent magnet plate 24. The polarity of the permanent magnet wedge 26 is the same as the polarity of the corresponding permanent magnet plate 24. The permanent wedge 26 includes a first permanent magnet wedge 261 and a second permanent magnet wedge 262. The first permanent magnet wedge 261 is corresponding to the first permanent magnet plate 241 and the polarity of the first permanent magnet wedge 261 is the same as the polarity of the first permanent magnet plate 241. The second permanent magnet wedge 262 is corresponding to the second permanent magnet plate 242 and the polarity of the second permanent magnet wedge 262 is the same as the polarity of the second permanent magnet plate 242.

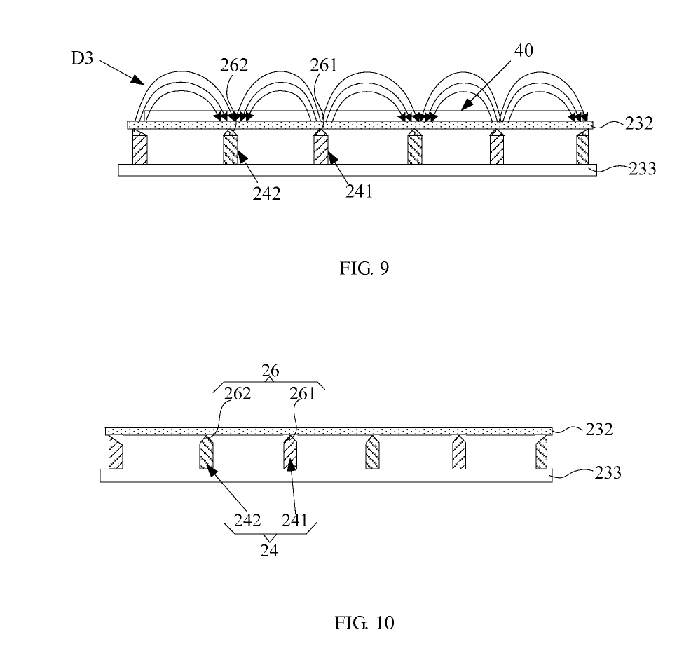

The magnetic wire of the magnetic field D2 generated by the permanent magnet plate 24 is irradiated from the anode to the cathode. When one end of the permanent magnet plate 24 includes a permanent magnet wedge 26, the polarity of the permanent magnet wedge 26 is the same as the corresponding permanent magnet plate 24. The distribution of the magnetic wire of the permanent magnet wedge 26 is the same as the corresponding permanent magnet plate 24 to enhance the even property of the magnetic field D2. Please refer to FIG. 9, which is a distribution view illustrating the magnetic wire of the magnetic field D3 on the substrate 40. By comparing to the magnetic field D2 in FIG. 6, the even property of the magnetic field D3 in FIG. 9 is better. In the practical process, the permanent magnet wedge 26 is integrated with the corresponding permanent magnet plate 24 to save the cost of the solo manufacturing of the permanent magnet wedge 26, as shown in FIG. 10.

A permanent magnet plate is configured to be the magnetic-field generating component and disposed at the bottom of the substrate by the sputtering and depositing process in the present invention. The permanent magnet plate can generate a magnetic field on the surface of the substrate, which is configured to do the sputtering and depositing process. The magnetic field is generated when the target is sputtered and generates a magnetic force to the charged molecules and the cathode ions, which are used to sputter on the substrate. Therefore, the situation that the charged molecules and the cathode ions with higher energy hit on the substrate to avoid the damage of the substrate and decrease the stress of the deposited thin film on the substrate so as to increase the yield of the products.

As described above, the present invention has been described with preferred embodiments thereof and it is understood that many changes and modifications to the described embodiments can be carried out without departing from the scope and the spirit of the invention that is intended to be limited only by the appended claims.

What is claimed is:

1. A magnetron sputtering system, comprising a chamber, wherein the chamber includes a target holder and a substrate holder opposite to each other, and the substrate holder is configured to dispose a substrate to be sputtered and deposited, wherein
the magnetron sputtering system further comprises a permanent magnet plate, and the permanent magnet plate is disposed within the substrate holder and configured to generate a magnetic field in a surrounding area of the to-be-sputtered/deposited substrate; and
a shielding board is disposed between the permanent magnet plate and a bottom of the chamber, and the substrate holder includes an anti-shielding board which is configured to dispose the to-be-sputtered/deposited substrate, and the shielding board is made of magnetic conductive material and the anti-shielding board is made of non-magnetic conductive material.

2. The magnetron sputtering system according to claim 1, wherein the anti-shielding board is integrated with the substrate holder.

3. The magnetron sputtering system according to claim 1, wherein the magnetic-field generating component includes at least two permanent magnet plates, and the at least two permanent magnet plates are equidistantly arranged along a horizontal direction which is perpendicular to a direction where the to-be-sputtered/deposited substrate passes through the chamber.

4. The magnetron sputtering system according to claim 3, wherein along the horizontal direction, a width formed by the at least two permanent magnet plates is greater than a width of the to-be-sputtered/deposited substrate; and along the direction where the to-be-sputtered/deposited substrate passes through the chamber, a length in each of the permanent magnet plate is greater than a length of the to-be-sputtered/deposited substrate.

5. The magnetron sputtering system according to claim 3, wherein the at least two permanent magnet plates includes a first permanent magnet plate and a second permanent magnet plate, both of which are alternatively arranged, and a polarity of the first permanent magnet plate is different from a polarity of the adjacent second permanent magnet plate.

6. The magnetron sputtering system according to claim 1, wherein a permanent magnet wedge is disposed between the anti-shielding board and the permanent magnet plate, a shape of the permanent magnet wedge is wedge, and a polarity of the permanent magnet wedge is the same as a polarity of the corresponding permanent magnet plate.

7. The magnetron sputtering system according to claim 3, wherein the magnetron sputtering system further includes a first horizontal motion controller configured to control the at least two permanent magnet plates to move back and forth along the horizontal direction.

8. The magnetron sputtering system according to claim 3, wherein a vertical direction is perpendicular to a horizontal surface of the anti-shielding board;
the magnetron sputtering system further includes a second horizontal motion controller configured to control the at least two permanent magnet plates to move along the vertical direction.

9. A magnetron sputtering system, comprising a chamber, wherein the chamber includes a target holder and a substrate holder opposite to each other, and the substrate holder is configured to dispose a substrate to be sputtered and deposited, wherein
the magnetron sputtering system further comprises a magnetic-field generating component, and the magnetic-field generating component is configured to generate a magnetic field in a surrounding area of the to-be-sputtered/deposited substrate.

10. The magnetron sputtering system according to claim 9, wherein the magnetic-field generating component is a permanent magnet plate which is disposed within the substrate holder.

11. The magnetron sputtering system according to claim 10, wherein the substrate holder includes an anti-shielding board which is configured to dispose the to-be-sputtered/deposited substrate, and the anti-shielding board is integrated with the substrate holder and made of non-magnetic conductive material.

12. The magnetron sputtering system according to claim 10, wherein a shielding board is disposed between the permanent magnet plate and a bottom of the chamber and is made of magnetic conductive material.

13. The magnetron sputtering system according to claim 11, wherein the magnetic-field generating component includes at least two permanent magnet plates, and the at least two permanent component magnet plates are equidistantly arranged along a horizontal direction, wherein the horizontal direction is perpendicular to a direction where the substrate passes through the chamber.

14. The magnetron sputtering system according to claim 13, wherein, along the horizontal direction, a width formed by the at least two permanent magnet plates is greater than a width of the to-be-sputtered/deposited substrate; and along the direction where the substrate passes through the chamber, a length in each of the permanent magnet plates is greater than a length of the to-be-sputtered/deposited substrate.

15. The magnetron sputtering system according to claim 13, wherein at least two permanent magnet plates are a first permanent magnet plate and a second permanent magnet plate, both of which are alternatively arranged, and a polarity of the first permanent magnet plate is different from a polarity of the adjacent second permanent magnet plate.

16. The magnetron sputtering system according to claim 11, wherein a permanent magnet wedge is disposed between the anti-shielding board and the permanent magnet plate, a shape of the permanent magnet wedge is wedge, and a polarity of the permanent magnet wedge is the same as a polarity of the corresponding permanent magnet plate.

17. The magnetron sputtering system according to claim 13, wherein the magnetron sputtering system further includes a first horizontal motion controller configured to control the at least two permanent magnet plates to move back and forth along the horizontal direction.

18. The magnetron sputtering system according to claim 13, wherein a vertical direction is perpendicular to a horizontal surface of the anti-shielding board;
the magnetron sputtering system further includes a second horizontal motion controller configured to control the at least two permanent magnet plates to move along the vertical direction.
